(19) United States
(12) Patent Application Publication
(10) Pub. No.: US 2010/0110144 A1
(43) Pub. Date: May 6, 2010

(54) Applying a Layer to a Nozzle Outlet

(76) Inventors: Andreas Bibl, Los Altos, CA (US); Jeffrey Birkmeyer, San Jose, CA (US)

Correspondence Address: FISH & RICHARDSON P.C., PO BOX 1022, MINNEAPOLIS, MN, 55440-1022, US

(21) Appl. No.: 12/606,712

(22) Filed: Oct. 27, 2009

Related U.S. Application Data
(60) Provisional application No. 61/110,439, filed on Oct. 31, 2008.

(51) Int. Cl. B41J 2/14; C23C 14/34; C25D 7/12

(52) U.S. Cl. 347/47; 204/192.25; 205/157

(57) ABSTRACT

A nozzle layer is described that has a semiconductor body having a first surface, a second surface opposing the first surface, and a nozzle formed through the body connecting the first and second surfaces, wherein the nozzle being configured to eject fluid through a nozzle outlet on the second surface, and a metal layer around the outlet on the second surface and at least partially inside the nozzle, the metal layer inside the nozzle being completely exposed.

This application claims the benefit of U.S. Provisional Application No. 61/110,439, filed Oct. 31, 2008, and incorporated herein by reference.

### BACKGROUND

This disclosure relates to fluid ejection devices. In some fluid ejection devices, fluid droplets are ejected from one or more nozzles onto a medium. The nozzles are fluidically connected to a fluid path that includes a fluid pumping chamber. The fluid pumping chamber can be actuated by an actuator, which causes ejection of a fluid droplet. The medium can be moved relative to the fluid ejection device. The ejection of a fluid droplet from a particular nozzle is timed with the movement of the medium to place a fluid droplet at a desired location on the medium. In these fluid ejection devices, it is usually desirable to eject fluid droplets of uniform size and speed and in the same direction in order to provide uniform deposition of fluid droplets on the medium.

### SUMMARY

In one aspect, a nozzle layer is described that has a semiconductor body having a first surface, a second surface opposing the first surface, and a nozzle formed through the body connecting the first and second surfaces, wherein the nozzle being configured to eject fluid through a nozzle outlet on the second surface, and a metal layer around the outlet on the second surface and at least partially inside the nozzle, the metal layer inside the nozzle being completely exposed.

In another aspect, a method includes applying a metal layer around a nozzle outlet and at least partially inside a nozzle of a semiconductor nozzle layer, and keeping the metal layer inside the nozzle completely exposed.

In another aspect, a method for making nozzle layers includes measuring a plurality of nozzle outlet widths in a nozzle layer; calculating an average nozzle outlet width of the plurality of nozzles; calculating a thickness for a cover layer to be applied to the nozzle layer based on a comparison between the average nozzle width and a desired nozzle width; and applying the cover layer with the thickness around each nozzle outlet and at least partially inside each nozzle.

In another aspect, a kit includes a first print head including a first semiconductor body having a first surface and a first plurality of fluid flow paths through the first semiconductor body with a first plurality of apertures on the first surface, the first plurality of apertures having a first average lateral aperture dimension, and a first cover layer on the first surface and at least partially inside the first plurality of apertures to provide nozzles having a first average lateral nozzle dimension; and a second print head including a second semiconductor body having a second surface and a second plurality of fluid flow paths through the second semiconductor body with a second plurality of apertures on the second surface, the second plurality of apertures having a second lateral aperture dimension different from the first average lateral aperture dimension, and a second cover layer on the second surface and at least partially inside the second plurality of apertures to provide nozzles having a second average lateral nozzle dimension approximately equal to the first average lateral nozzle dimension.

Implementations may include one or more of the following features. The metal layer can include a metal selected from the group consisting of titanium, gold, platinum, rhodium, tantalum, nickel, and nickel chromium. The metal layer can be chemically resistant to alkaline fluids. The metal layer can have a thickness of about 1 micron or greater. The nozzle layer can also have a non-wetting coating on the metal layer on the second surface. The metal layer can be between about 0.1 micron and about 10 microns thick. The metal layer can be completely exposed around the outlet on the second surface and inside the nozzle. The nozzle can have tapered walls or straight walls connecting the first surface to the second surface. The metal layer can shape the outlet to have curved edges. The curved edges can have a radius of curvature of about 1 micron or greater. The outlet can be a square. The semiconductor body of the nozzle layer can comprise silicon. Applying the metal layer can comprise sputtering metal or electroplating metal on the sputtered metal. The method can further include securing the nozzle layer to a fluid flow path body. The method can also include keeping the metal layer around the nozzle outlet completely exposed. The nozzle outlet can be located on an outer surface of the nozzle layer and the metal layer around the nozzle outlet can be on the outer surface, and the method further can include applying a non-wetting coating on the metal layer on the outer surface of the nozzle layer but not inside the nozzle. The method can include shaping the nozzle outlet using the metal layer to have curved edges. Measuring a plurality of nozzle outlet widths can include using an optical measurement tool. The cover layer can comprise metal.

Implementations may include one or more of the following advantages. Shaping a nozzle outlet to have curved edges and/or corners can alleviate problems associated with sharp-edged outlets: nozzles can be less likely to become clogged with debris, jetting straightness can be improved, nozzles can be more durable and drop size can be more uniform.

Without being limited to any particular theory, the sharp edges of the nozzle outlets can act like a blade and shave off portions of a maintenance device (e.g., wiper), and the wiping action of a wiper can push this debris into the nozzles and clog them. Shaping the nozzle outlet to have curved edges can reduce the tendency of the nozzle to create and trap debris.

Without being limited to any particular theory, a substantially square-shaped nozzle outlet or any outlet having sharp or pointed corners can have difficulty ejecting fluid drops in a straight line because of high fluid surface tension forces in the corners. The high surface tension force in a sharp corner can pull the drop toward that corner causing the drop to be ejected at an angle. Shaping the outlet to have curved corners can reduce the tendency of the drop to be pulled toward a corner and improve jet straightness. In addition, during fluid ejection, if fluid splashes back and collects on an outer surface of the nozzle plate, then this fluid can interfere with subsequent fluid drops ejected. For example, the fluid on the surface can coalesce near the nozzle outlet and when a drop is ejected, the fluid on the nozzle surface pulls the ejected drop to one side affecting the straightness of the drop and causing drop placement errors on the printed medium. It is difficult for the coalesced fluid on the surface to enter back inside the nozzle if the edges are sharp, but with curved edges and corners, without being limited to any particular theory, the fluid can more easily re-enter the nozzle so that it does not affect the straightness of the next ejected fluid drop.

Without being limited to any particular theory, the sharp or pointed edges of a nozzle formed of semiconductor material can be fragile and susceptible to damage and, if damaged, the nozzle outlet can become irregularly shaped and eject drops at an angle other than straight. Further, damage to the nozzle outlet can increase the dimensions of the outlet (e.g., width or diameter) and, therefore, increase the drop volume of the ejected drops. Shaping the outlet to have curved edges and corners can improve the durability of the nozzles.

Twinning is the term used to describe the drop placement errors caused by jets ejecting drops at an angle rather than in a straight line. For example, when a jet ejects a drop at angle, this drop may land closer to a neighboring drop than desired. The two drops may merge together and the surface tension of the merged drops can prevent the drops from being able to completely spread leaving white space on the printed medium. Improving jet straightness, for example, by shaping the nozzles to have curved features can prevent twinning.

Applying a layer of an inorganic, non-metallic material, a metal layer, or both around the nozzle outlet and partially inside the nozzle can strengthen the nozzle outlet against damage and/or make the nozzle surface chemically resistant. The nozzle can be strengthened by applying one or more of these layers that are more durable than the underlying material of the nozzle layer and by increasing the radius of curvature at the edges and corners. A metal layer or oxide layer doped with a metal can reduce electric field buildup on the nozzle layer surface and/or improve galvanic compatibility in the printhead. One or more layers can be applied to the nozzle outlet with or without curved edges and/or corners.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional side view of an apparatus for fluid droplet ejection.

FIG. 2A is a cross-sectional side view of an apparatus including a nozzle layer having a nozzle with tapered walls.

FIG. 2B is a bottom view of a nozzle outlet formed in a nozzle layer.

FIG. 2C is a cross-sectional side view of a nozzle with straight walls.

FIG. 3 is a scanning electron microscope (SEM) image showing a bottom view of a damaged outlet of a nozzle.

FIG. 4 is a flowchart of a method of making a nozzle layer.

FIGS. 5A-F are diagrams of applying and removing an oxide layer to a nozzle layer, applying a protective layer, and securing the nozzle layer to a fluid path body.

FIG. 6A is a cross-sectional side view of a nozzle having tapered walls.

FIG. 6B is a bottom view of the nozzle in FIG. 6A.

FIG. 6C is a cross-sectional side view of a metal layer applied to the nozzle walls and around the nozzle outlet.

FIG. 6D is a bottom view of a nozzle layer in FIG. 6C.

FIG. 7A is a SEM image showing a cross-sectional side view of a nozzle with tapered walls and an inorganic oxide layer grown on the surfaces of the nozzle.

FIG. 7B is a SEM image showing a cross-sectional perspective view of only the right side of the nozzle after the oxide layer is removed and another oxide layer is re-grown.

FIG. 7C is a cross-sectional perspective view of a nozzle with an oxide layer, the nozzle has tapered walls and curved edges and corners.

FIG. 7D is a bottom view of the nozzle layer showing the nozzle outlet with curved corners.

FIG. 7E is a bottom view of the nozzle layer including a protective layer showing the nozzle outlet with curved corners having a reduced radius of curvature.

FIG. 8 is a SEM image showing a cross-sectional side view of a nozzle layer secured to a descender layer.

Like reference symbols in the various drawings indicate like elements.

### DETAILED DESCRIPTION

Fluid droplet ejection can be implemented with a substrate, for example a microelectromechanical system (MEMS), including a fluid flow path body, a membrane, and a nozzle layer. The flow path body has a fluid flow path formed therein, which can include a fluid fill passage, a fluid pumping chamber, a descender, and a nozzle having an outlet. An actuator can be located on a surface of the membrane opposite the flow path body and proximate to the fluid pumping chamber. When the actuator is actuated, the actuator imparts a pressure pulse to the fluid pumping chamber to cause ejection of a droplet of fluid through the outlet. Frequently, the flow path body includes multiple fluid flow paths and nozzles.

A fluid droplet ejection system can include the substrate described. The system can also include a source of fluid for the substrate. A fluid reservoir can be fluidically connected to the substrate for supplying fluid for ejection. The fluid can be, for example, a chemical compound, a biological substance, or ink.

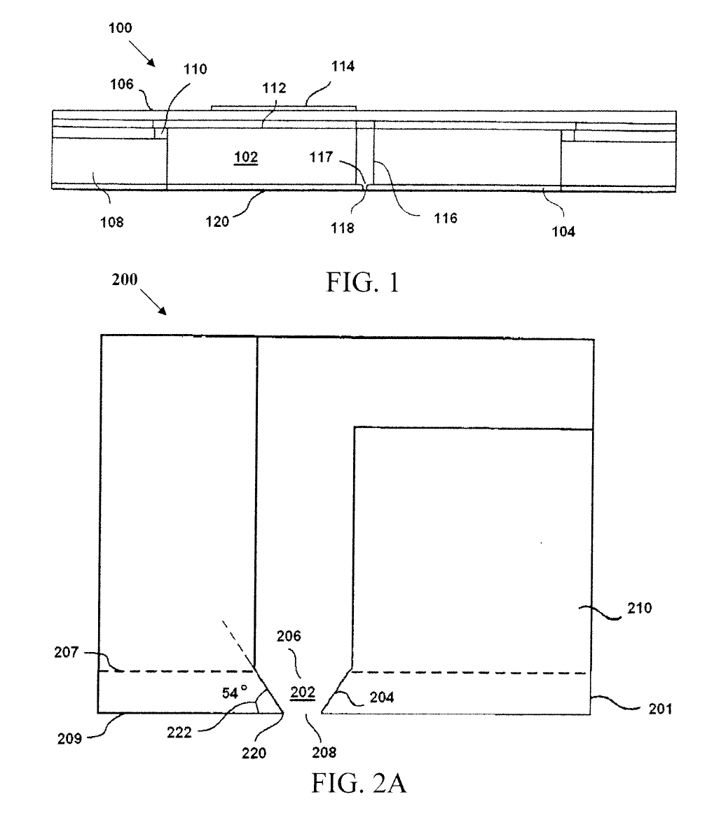

Referring to FIG. 1, a cross-sectional schematic diagram of a portion of a microelectromechanical device, such as a printhead in one implementation is shown. The printhead includes a substrate 100. The substrate 100 includes a fluid path body 102, a nozzle layer 104, and a membrane 106. A fluid reservoir supplies a fluid fill passage 108 with fluid. The fluid fill passage 108 is fluidically connected to an ascender 110. The ascender 110 is fluidically connected to a fluid pumping chamber 112. The fluid pumping chamber 112 is in close proximity to an actuator 114. The actuator 114 can include piezoelectric material, such as lead zirconium titanate (PZT), sandwiched between a drive electrode, and a ground electrode. An electrical voltage can be applied between the drive electrode and the ground electrode of the actuator 114 to apply a voltage to the actuator and thereby actuate the actuator. A membrane 106 is between the actuator 114 and the fluid pumping chamber 112. An adhesive layer (not shown) can secure the actuator 114 to the membrane 106.

A nozzle layer 104 is secured to a bottom surface of the fluid path body 102 and can have a thickness between about 1 and 100 microns (e.g., between about 5 and 50 microns or between about 15 and 35 microns). A nozzle 117 having an outlet 118 is formed in an outer surface 120 of the nozzle layer 104. The fluid pumping chamber 112 is fluidically connected to a descender 116, which is fluidically connected to the nozzle 117. While FIG. 1 shows various passages, such as a fluid fill passage, pumping chamber, and descender, these components may not all be in a common plane. In some implementations, two or more of the fluid path body, the nozzle layer, and the membrane may be formed as a unitary body.

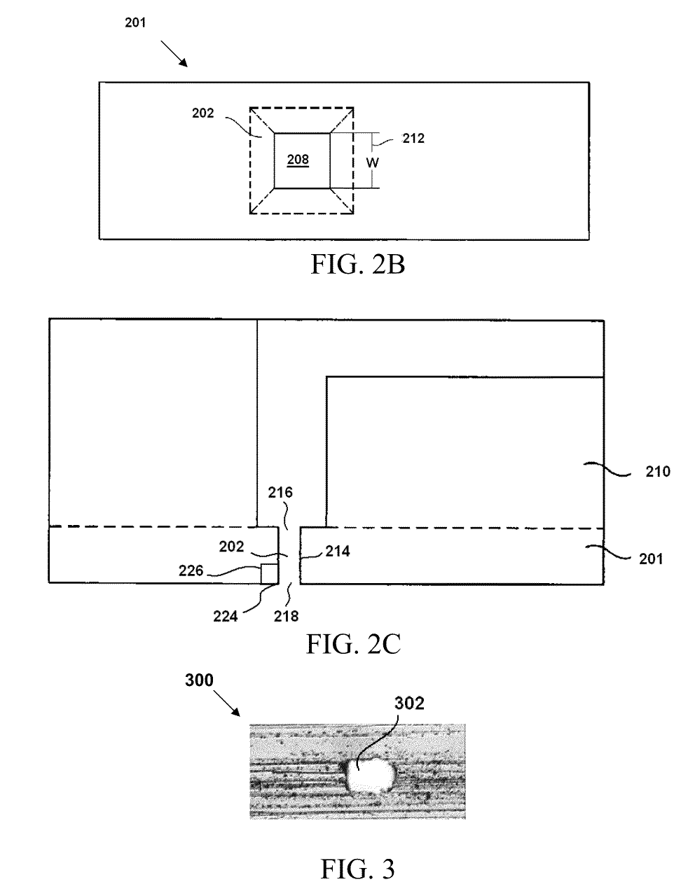

FIG. 2A shows a module 200 including a nozzle layer 201 attached to a fluid path body 210. The nozzle layer 201 includes a nozzle 202 having tapered walls 204 connecting an inlet 206 on a first surface 207 to an outlet 208 on a second surface 209. The outlet 208 can be narrower than the inlet 206. The first surface 207 of the nozzle layer 201 can be secured to the fluid path body 210 (e.g., bonding such as anodic bonding, silicon-to-silicon direct wafer bonding, or bonding with an adhesive like BCB). Anodic bonding and examples of materials used in anodic bonding are described in U.S. Pat. No. 7,052,117, the entire contents of which are incorporated by reference. The nozzle layer and fluid flow path body can be made of a semiconductor material, such as silicon, e.g., single crystal silicon. Fluid drops can be ejected through the outlet 208 formed in the second surface 209. FIG. 2B shows a square-shaped outlet 208 having a side with a width, W, 212, such as between about 1 microns and about 100 microns, such as between about 1 and 10 microns, about 10 and 30 microns, or about 5 and 50 microns.

Alternatively, FIG. 2C shows a nozzle 202 having straight walls 214 connecting the nozzle inlet 216 to the nozzle outlet 218. In general, the edge of the outlet can have an angle of about 90 degrees or less (e.g., 45 degrees or less) measured from the plane of the outer surface of the nozzle layer. FIG. 2A shows a nozzle having an outlet edge 220 with an angle 222 of about 54 degrees, whereas FIG. 2C shows an outlet edge 224 having an angle 226 of about 90 degrees.

The outlets 208 and 218 shown in FIGS. 2A and 2C can be square-shaped (as shown in FIG. 2B), circular, elliptical, polygonal, or any other shape suitable for droplet ejection. If the outlet is other than square, the longest dimension can be, for example, between about 1 micron and about 100 microns, such as between about 1 and 10 microns, about 10 and 30 microns, or about 5 and 50 microns. This outlet size can produce a useful fluid droplet size for some implementations. The nozzle layer can be formed in a semiconductor body, such as silicon, and the nozzle can be formed in the semiconductor body by plasma etching (e.g., deep reactive ion etching), wet etching (e.g., KOH etching), or another process. A plurality of nozzle layers can be formed in a single silicon wafer and processed together. The silicon wafer including the plurality of nozzle layers can also be bonded to other wafers, such as a wafer including a plurality of fluid flow path bodies. The wafer including the plurality of flow path bodies can also be bonded to another wafer including a plurality of membranes.

The nozzles in FIGS. 2A-2C include outlets having sharp edges, which can be broken or chipped, such as during maintenance operations or handling of the printhead. Sharp edges can include an edge having a radius of curvature less than 0.1 micron. During maintenance operations, a wiper can be used to wipe off excess fluid from the outer surface of the nozzle layer. Since the outlet has sharp edges, the edges can act like a blade and shave off portions of the wiper, subsequently, leaving debris in the nozzle and/or damaging the edges of the nozzle outlet. In other cases, the fluid being ejected may attack the material of the nozzle layer and etch away the edges of the outlet.

FIG. 3 is a SEM image showing a nozzle layer 300 with a square-shaped nozzle outlet 302 that has been damaged. For example, the right side of the nozzle outlet has been chipped and broken and is now irregularly shaped. Such irregular shapes no longer eject fluid drops in a straight line. Rather the drops will be ejected at an angle, causing drop placement errors on the printed medium. In the case of a nozzle with tapered walls, the width of the nozzle outlet can significantly increase as the edges of the outlet are chipped away, causing not only drop placement errors due to trajectory errors and decreases in velocity but also undesirable increases in fluid drop volumes.

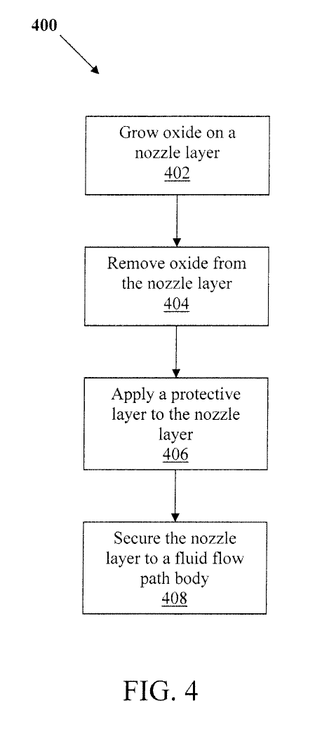

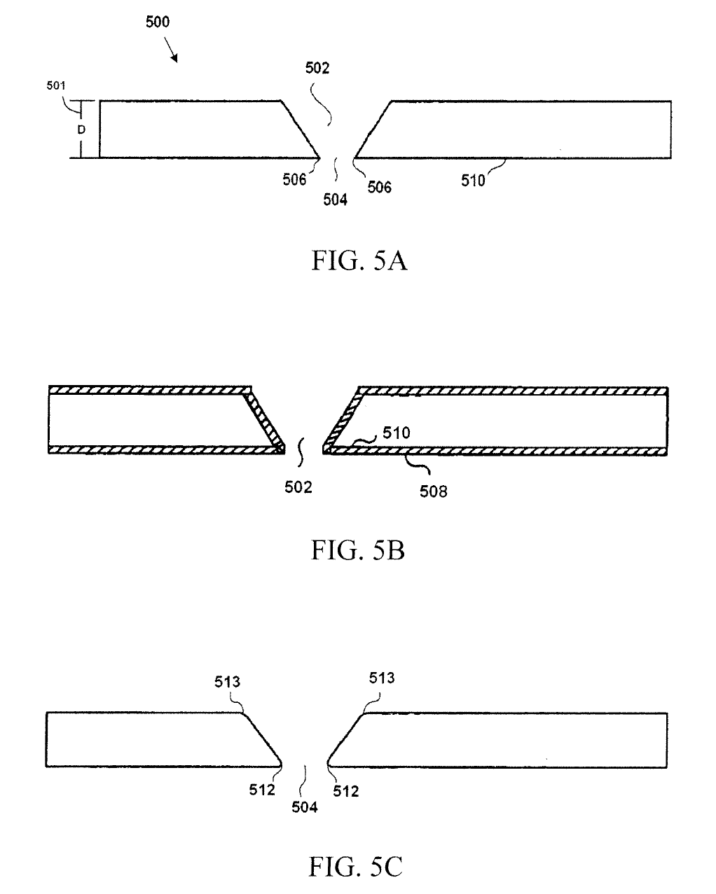

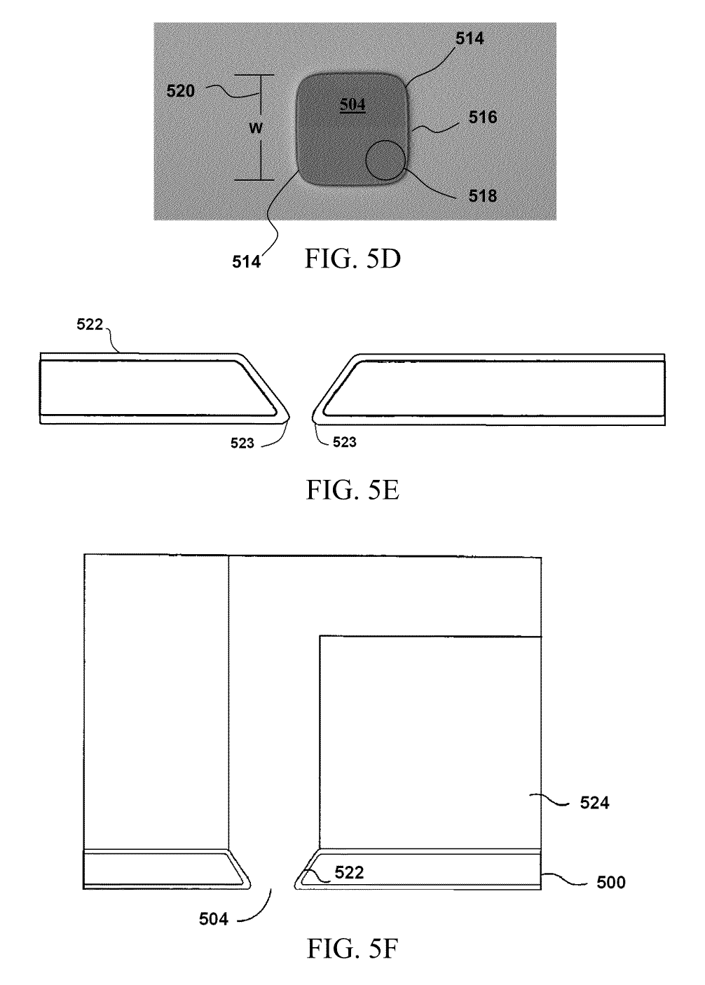

FIG. 4 is a flowchart 400 of a method of making a nozzle layer, such as the nozzle layers in FIGS. 2A-2C. FIGS. 5A-5E are diagrams illustrating the fabrication of a nozzle layer, for example, for a printhead. FIGS. 5A-5E show a nozzle layer 500 separate from a fluid flow path body, e.g., the fluid flow path body 210 in FIG. 2A. Initially, as shown in the cross-sectional view of FIG. 5A, a nozzle layer 500 having a depth, D, 501 and a nozzle 502 having an outlet 504 is fabricated (step 401). The nozzle layer 500 and nozzle 502 can be fabricated with conventional techniques and can have features discussed above with respect to FIGS. 2A-2C. In particular, the outlet 504 can have sharp edges 506. As shown in FIG. 5B, a layer of an inorganic oxide 508 is thermally grown on the exposed surfaces of the nozzle layer 500 (step 402). In some implementations, the inorganic oxide 508 can be grown on only a portion of the nozzle layer, such as around the outlet 504 on the outer surface 510 and at least partially inside the nozzle 502. Next, the inorganic oxide 508 is removed (step 404), for example, by using hydrofluoric acid, as shown in FIG. 5C.

The inorganic oxide (e.g., silicon dioxide) can have a thickness of about 0.5 microns or greater, such as about 1 micron or greater, for example, between about 1 and 10 microns or between about 2 and 5 microns.

Without being limited to any particular theory, when thermal oxide is grown on a semiconductor (e.g., silicon, e.g., single crystal silicon) surface, the oxide both grows on the silicon surface and into the silicon surface, such that about 46% of the oxide thickness is below the original silicon surface and 54% is above it. When growing thermal oxide, an oxidant (e.g., water vapor or oxygen) combines with silicon atoms at the silicon surface to form a layer of silicon oxide on the silicon surface. As the silicon oxide layer increases in thickness, the oxidant has a longer distance to travel to reach the silicon surface. Again without being limited to any particular theory, the distance the oxidant has to travel at the corners and edges of the nozzle outlet is even greater than the distance the oxidant has to travel at the straight or flat surfaces. Since the oxidant has a longer distance to travel at the corners and edges, the silicon surface at the corners is eroded slower causing the corners and edges to be rounded or curved. Along with the corners, the silicon edges of the outlet are also eroded at a different rate than the flat surfaces causing the edges to be curved, but not as much as the corners. FIG. 5C shows the curved edges 512 and FIG. 5 D shows the curved corners 514. In an implementation, a layer of silicon oxide (e.g., 5 microns thick) is thermally grown on a silicon nozzle layer (e.g., 30 microns thick) at a temperature between about 800° C. and 1200° C. and, subsequently, placed in a bath of hydrofluoric acid (e.g., for about 7 minutes) to remove the silicon oxide. In some implementations, after removing the oxide layer, a subsequent oxide layer can be re-grown and removed. With each oxide layer that is grown and removed, the radius of curvature of the edges and corners can be further increased.

Alternatively, to shape the sharp edges and corners to be curved, an etchant (e.g., KOH) can be used to etch the sharp features of the semiconductor nozzle layer to create curved edges and corners, for example, by placing the nozzle layer in a KOH bath for a predetermined time.

FIG. 5C shows a cross-sectional view of the nozzle layer 500 after the oxide layer 508 has been removed leaving a nozzle 502 that now has an outlet 504 with curved edges 512. The curved edges can have a radius of curvature greater than 0.1 micron, such as 0.4 microns or greater. The edges 513 of the nozzle inlet are also curved when the oxide is removed. The amount of curvature of the edges and corners can depend on the thickness of the oxide grown on the semiconductor nozzle layer. As the thickness of the oxide increases the curvature of the edges and corners can also increase.

FIG. 5D is an optical microscope photograph showing a bottom view of the nozzle outlet 504 having curved corners 514. Without being limited to any particular theory, the curved corners can improve the straightness of the drop trajectory by reducing the high fluid surface tension forces in the corners and/or by allowing fluid on an outer surface of the nozzle layer to more easily re-enter the nozzle outlet. The outlet 504 in FIG. 5D has straight sides 516 connected by curved corners 514 that can have a radius of curvature 518 of about 0.5 microns or greater, such as 1 micron or greater, for example, between about 1 and 10 microns or between about 2 and 5 microns.

After the oxide is removed, FIG. 5E shows a protective layer 522 (e.g., an inorganic, non-metallic layer, such as oxide, a metal layer, or a conductive layer) applied to the nozzle layer 500 (step 406). The protective layer can be a material more durable than the semiconductor material and can strengthen the semiconductor material, especially the sharp features that are susceptible to damage, such as during maintenance and handling. Inorganic, non-metallic materials can include oxide, diamond-like carbon, or a nitride like silicon nitride or aluminum nitride. Applying a protective layer, for example, re-growing another oxide layer or sputtering a metal layer can increase the curvature of the edges 523 more so than the curvature of the silicon edges 512 in FIG. 5C. The radius of curvature of edges 523 can be of about 0.5 microns or greater, such as 1 micron or greater, for example, between about 1 and 10 microns or between about 2 and 5 microns. However, if the nozzle outlet is, for example, square-shaped, then the re-grown oxide can reduce the curvature of the corners, and if too much oxide is re-grown, then the oxide can re-square the corners. Therefore, in some implementations, to avoid re-squaring the corners 514 of FIG. 5D, the thickness of the re-grown oxide can be less than the thickness of the removed oxide 508 in FIG. 5B. For example, the re-grown oxide can be about 50% or less than the thickness of the removed oxide layer. The curved edges 523 can be less susceptible to chipping and breaking and can prevent the nozzle 502 from being clogged because the curved edges 523 are less likely to shave off debris from a maintenance device.

While FIG. 5E shows a protective layer 522 covering the surfaces of the nozzle layer 500, the protective layer can cover only a portion of the nozzle layer, such as the areas around the nozzle outlet and partially inside the nozzle 504. Alternatively, the protective layer can be only on the outer surface of the nozzle layer around the nozzle outlet and not inside the nozzle. In the case of a nozzle layer having a low surface energy (e.g., a contact angle of about 20° or less), such as silicon, the outer surface of the nozzle layer can be contaminated by process contaminants, like low tack tape, silicones, and outgassing polymers. These contaminants can create non-wetting areas near the nozzle outlets having contact angles of about 70° or greater. A protective layer having a high surface energy (e.g., a contact angle of about 70° or greater), such as gold, can be applied on the outer surface of the silicon nozzle layer, such that the contaminants and the protective layer have about the same surface energy. By including a protective layer having a high surface energy on the outer surface of the nozzle layer, the nozzle layer can be contaminant resistant.

FIG. 5F shows the nozzle layer 500 secured to a fluid path body 524 (e.g., carbon body or silicon body) (step 408). The nozzle layer can be secured to the fluid path body by anodic bonding, silicon-to-silicon direct wafer bonding, using an adhesive, such as an epoxy like benzocyclobutene (BCB), or other securing means.

Protective layer 522 can be silicon nitride, which can be tougher and more wear resistant than silicon or silicon oxide, especially if processed at higher temperatures (e.g., 1000° C. or greater). Processing at higher temperatures creates a nitride layer that is denser and has fewer pinholes. Since the nitride is tougher than oxide, a thinner layer can be applied to a nozzle, for example, the nitride layer can have a thickness less than 0.5 micron, such as between about 0.05 and 0.2 micron. If necessary, silicon nitride can also be deposited at a lower temperature (e.g., 350° C.), which can be important if the nozzle layer is connected to other heat-sensitive components, such as a piezoelectric actuator that can depole if exposed to temperatures above its Curie temperature.

The protective layer (e.g., non-metallic layer or metal layer) can be selected based on its chemical resistance to the fluid being ejected. A protective layer is chemically resistant, for example, if the layer does not react with the fluid. For instance, the fluid does not significantly attack, etch, or degrade the protective layer. The protective layer can also be selected for its durability against maintenance operations, such as wipers, and/or its robustness compared to the underlying material of the nozzle layer (e.g., silicon).

Protective layers with fewer pinholes can better protect the semiconductor material from being attacked by aggressive fluids like alkaline inks The protective layer 522 can be about 10 nanometers or greater, such as between about 10 nanometers and 20 microns thick.

In some implementations, the protective layer can include a conductive material (e.g., non-metallic or metallic) so as to reduce electric field buildup due to electrostatic charges developed on the nozzle surface, for example, by connecting the conductive material to ground. Conductive materials can also be used to improve the galvanic compatibility in a printhead. The conductive material can be an oxide, such as indium tin oxide (ITO), potentially doped with metal such as cesium or lead.

In some implementations, the protective layer can include be a metal layer. The metal can be tougher than the semiconductor material (e.g., silicon) of the nozzle layer. Metal layers can, for example, include titanium, tantalum, platinum, rhodium, gold, nickel, nickel chromium, and combinations thereof. In some implementations, the protective layer can be applied to a nozzle outlet with or without curved edges and/or corners. For example, a protective layer can be applied to the nozzle outlet without first growing and removing an oxide layer.

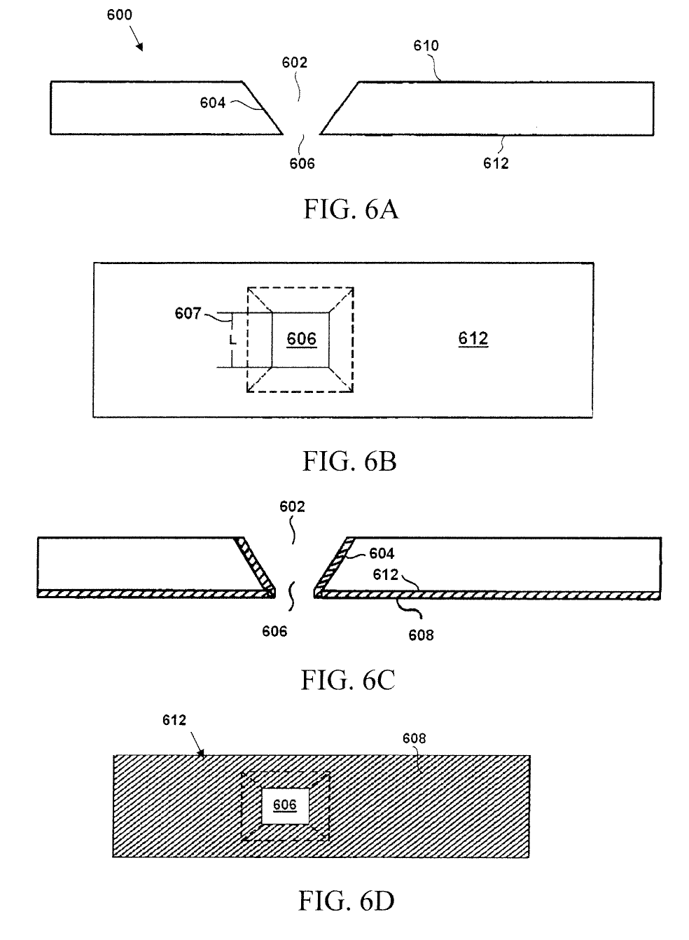

FIGS. 6A-6D show diagrams of a metal layer (e.g., titanium) being applied to a nozzle layer, in which the nozzle outlet does not have curved edges or corners. FIG. 6A shows a nozzle layer 600 having a nozzle 602 with tapered walls 604, and FIG. 6B shows a bottom view of the nozzle outlet 606, which is square-shaped having a side with a length, L, 607. Other nozzle outlet shapes are possible, such as circular, elliptical, or polygonal. FIG. 6C shows a metal layer 608 applied to a few surfaces of the nozzle layer 600 including inside the nozzle on the tapered walls 604, around the nozzle outlet 606, and on the outer surface 612 of the nozzle layer 600. The metal layer on the inside of the nozzle may be thinner than the metal layer on the outer surface 612 due to the deposition process (e.g., sputtering). For a metal layer with a more uniform thickness, a thin metal layer can be sputtered on the nozzle layer (e.g., about 200 Angstroms or greater) and a second metal layer can be electroplated on the sputtered metal layer (e.g., 980 nm or greater). FIG. 6D shows the nozzle outlet 606 having a metal layer 608 applied to the outer surface 612 of the nozzle layer.

In some implementations, the metal layer of FIGS. 6C and 6D is exposed meaning that subsequent layers are not applied on top of the metal layer. The metal layer can be completely exposed both on the outer surface and inside the nozzle. While a native oxide layer may grow on the surface of the metal, this layer is on the Angstrom level and for purposes of this application would still be considered exposed metal. For some metals, such as titanium, the native oxide layer provides the chemical inertness that makes the metal layer resistant to aggressive fluids.

In some implementations, only the metal layer inside the nozzle is completely exposed while a non-wetting coating is applied to the metal layer on the outer surface. The non-wetting coating provides a hydrophobic surface that causes fluid on the outer surface to bead up rather than form a puddle near the nozzle outlet. The non-wetting coating is not inside the nozzle because a non-wetting coating inside the nozzle can affect the position of the meniscus and the ability of the fluid to properly wet the area around the nozzle outlet. Non-wetting coatings are described in U.S. Patent Publication Nos. 2007/0030306 (entitled “Non-Wetting Coating on a Fluid Ejector” filed by Okamura et al. on Jun. 30, 2006 and published on Feb. 8, 2007), 2008/0150998 (entitled “Pattern of Non-Wetting Coating on a Fluid Ejector” filed by Okamura on Dec. 18, 2007 and published on Jun. 26, 2008), and 2008/0136866 (entitled “Non-Wetting Coating on a Fluid Ejector” filed by Okamura et al. on Nov. 30, 2007 and published on Jun. 12, 2008), the entire contents of which are incorporated by reference. Although FIG. 6C shows the metal layer 608 covering entire surfaces, the metal layer can be applied such that it covers only a portion of the nozzle layer, for example, the area around the nozzle outlet and at least partially inside the nozzle near the outlet. The metal layer can be selected to be chemically resistant to a particular fluid (e.g., alkaline fluid with a high pH or acidic fluid with a low pH). Examples of chemically resistant metals can include titanium, gold, platinum, rhodium, and tantalum. In an implementation, a titanium or tantalum metal layer, which is chemically resistant to alkaline fluids, can be applied to a silicon nozzle layer of a printhead to protect the nozzle outlets from being etched when ejecting drops of an alkaline fluid.

The metal layer can be about 0.1 micron or greater, such as about 0.2 to 5 microns thick (e.g., 2 to 2.5 microns). For durability, the metal layer can be about 1 micron or greater, such as about 1 to 10 microns thick. The metal layer can be electrically conductive. Along with making the nozzle layer more durable, the metal layer can be applied, for example, by vacuum deposition (e.g., sputtering) or by a combination of vacuum deposition and electroplating, such that the metal layer shapes the edges of the nozzle outlet to be curved. Electroplated metal can provide a more conformal, uniform layer than sputtered metal and can increase the radius of curvature of the nozzle outlet edges. For example, the metal layer on the outlet edges can have a radius of curvature of 1 micron or greater, such as 2 to 5 microns.

When applying a protective layer (e.g., metal layer), additional material can be added to change the width of the nozzles to make the nozzles more uniform from printhead to printhead. For example, if the desired nozzle outlet width is 10 microns, and a first nozzle layer of a first print head has an average outlet width of 11 microns and the a second nozzle layer of a second print head has an average outlet width of 12 microns, then an additional 1 micron of material (e.g., metal) can be applied around the nozzles of the first nozzle layer and 2 microns on the second nozzle layer, such that the first and second nozzle plates both have an average outlet width of 10 microns. The width of the individual nozzles can be measured using an optical measurement tool available from JMAR Technologies or Tamar Technology.

Other combinations are possible, such as a first layer of an inorganic, non-metallic material (e.g., oxide, silicon nitride, or aluminum nitride) and a second layer of a metal. With a nozzle layer made of silicon, precise nozzle features can be etched into the silicon, for example, by photolithography and dry or wet etching that may not be possible with a metal nozzle layer, especially thicker nozzle layers (e.g., 3-100 microns). By depositing a thin metal layer on the silicon, the nozzle plate can not only have fine features, but also be durable and chemically inert.

The non-metallic and metal layer(s) can be applied, for example, by PVD, CVD like PECVD, or thermally grown in the case of thermal oxide, and can have the same thickness as the removed oxide layer, or it can be thicker or thinner, for example, the thickness can be between about 0.1 micron or greater, about 0.5 to 20 microns, such as about 1 to 10 microns. When applying the layer(s) to sharp edges, the layer(s) can provide a radius of curvature of about 0.5 micron or greater, such as 1 micron or greater, such as about 1 to 5 microns. In the case of nozzles with corners, the additional layer(s) may slightly reduce the curvature in the corners. Thus, the layer(s) should be thin enough to avoid re-squaring the corners of the nozzle outlet.

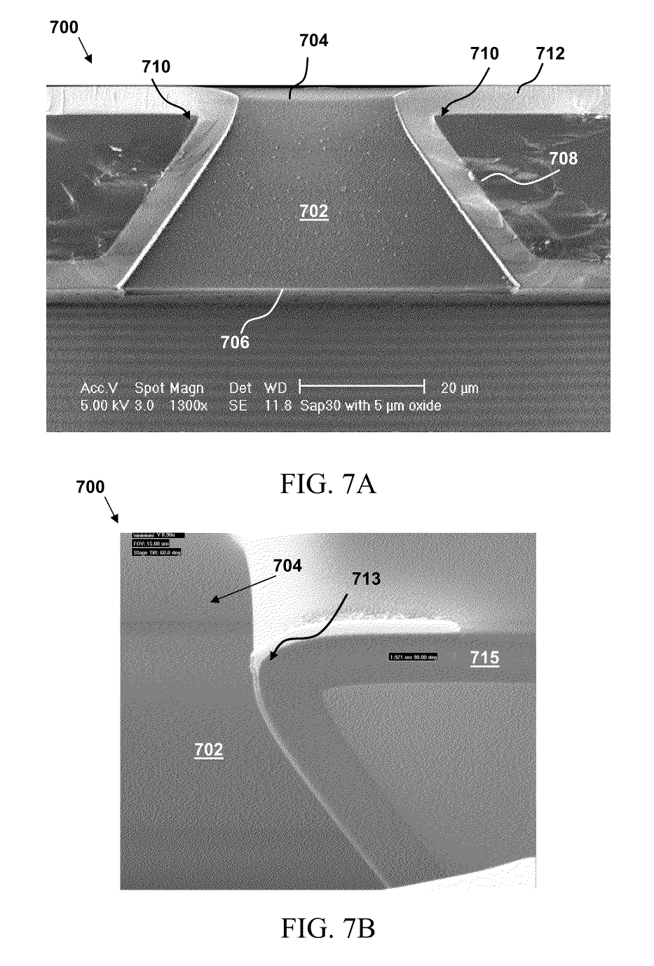

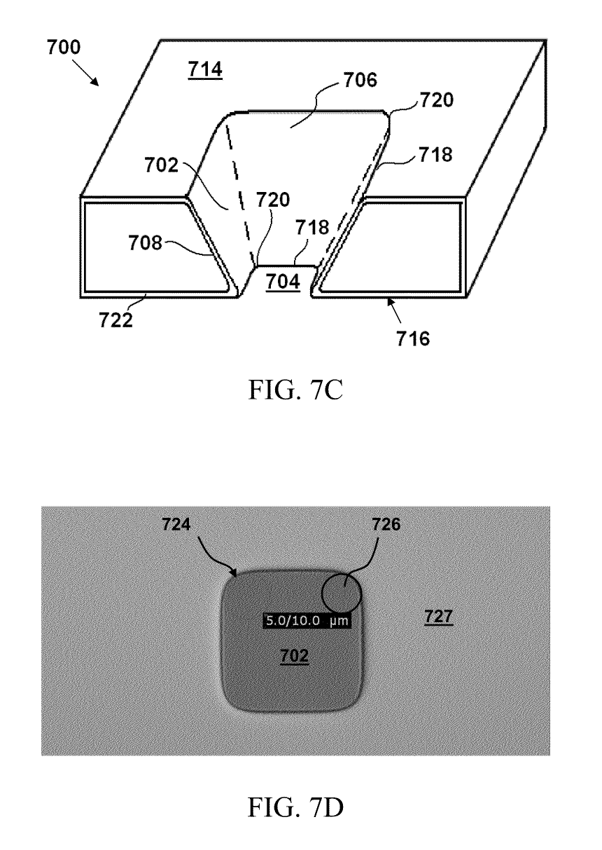

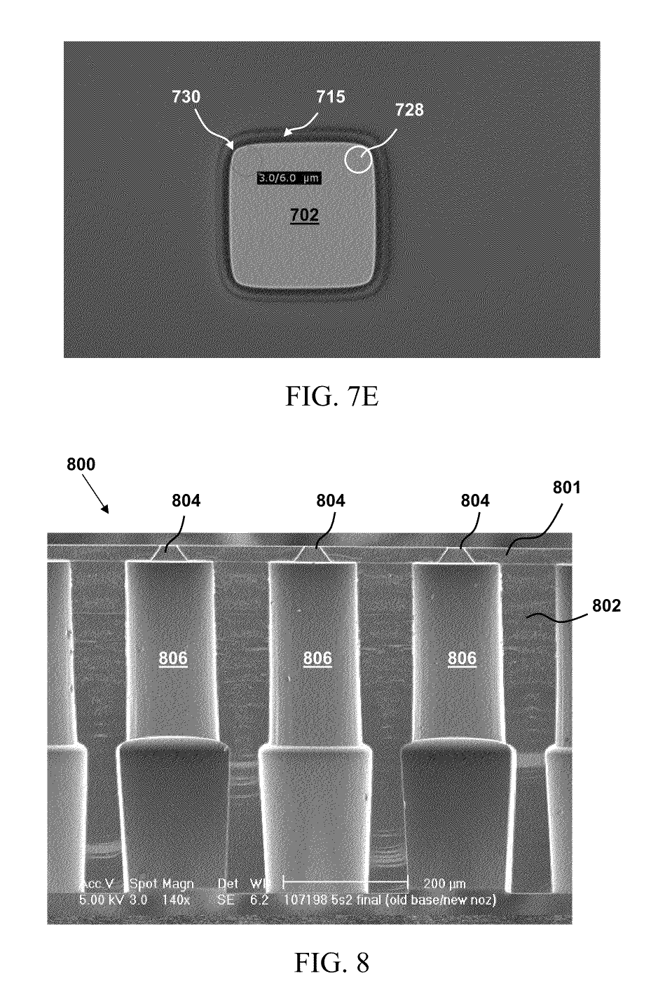

FIG. 7A is a SEM image of a nozzle layer 700 showing a cross-sectional side view of a nozzle 702 formed in a semiconductor nozzle layer (e.g., silicon). The outlet 704 of the nozzle 702 is located near the top of the picture and the inlet 706 is closer to the bottom. The nozzle 702 has tapered walls 708 and edges 710 that have been eroded slightly from the growth of the thermal oxide layer 712 such that the edges 710 are slightly curved. As explained above, growing the oxide layer 712 on the surfaces of the nozzle layer 702 shapes the edges and the corners to be curved.

FIG. 7B is a SEM image showing a cross-sectional perspective view of only the right side of the nozzle 702 after the oxide layer 712 is removed and an oxide layer 715 is re-grown on the silicon surface. The edge 713 has a radius of curvature greater than the curvature of the silicon edge 710 in FIG. 7A.

FIG. 7C is a schematic of a cross-sectional perspective top view of a nozzle 702 formed in a nozzle layer 700 having tapered walls 708 starting with an inlet 706 on a first surface 714 and ending in an outlet 704 on a second surface 716. The tapered walls 708 form a truncated-pyramid shape, which can be formed by KOH etching. The nozzle inlet 706 and outlet 704 have straight sides 718 connected by curved corners 720 and the inlet 706 is connected to the outlet 704 by tapered walls 708. A protective layer 722, such as an inorganic, non-metallic and/or metal layer, is applied to the nozzle layer 700 having curved features. In some implementations, the tapered walls can be conical or polygonal rather than pyramidal. Alternatively, the nozzle can have a combination of tapered walls and straight walls, for example, a first portion of the nozzle starting at the nozzle inlet can have tapered walls that connect to a second portion of the nozzle having straight walls that end at the nozzle outlet, such as the nozzles described in U.S. Pat. No. 7,347,532, the entire contents of which are incorporated by reference.

Referring back to FIGS. 7A and 7B, in an implementation, the oxide layer 712 (shown in FIG. 7A) can be thermally grown to a thickness of about 5 microns and subsequently removed, which shapes the silicon edge 710 to have a radius of curvature of about 0.4 micron. An oxide layer 715 (shown in FIG. 7B) having a thickness of about 2 microns is re-grown on the silicon surface such that the radius of curvature at the oxide edge 713 is about 2.5 microns. As mentioned before, while re-growing an oxide layer increases the radius of curvature of the edges 713, it can decrease the radius of curvature of the corners. For example, FIG. 7D shows the nozzle outlet 702, after growing and removing the 5 micron thick oxide layer 712 (from FIG. 7A), with corners 724 having a radius of curvature 726 of about 5 microns at the silicon surface 727. In some implementations, the radius of curvature of the corner 724 can be about equal to the thickness of the removed oxide layer 712. FIG. 7E shows the nozzle outlet 702 after the 2 micron thick oxide layer 715 is re-grown, the radius of curvature 728 at the corner 730 is reduced to about 3 microns. To limit the reduction in curvature of the corners, the re-grown oxide can be thinner than the removed oxide layer.

The nozzle layer can be processed separately as shown in FIGS. 5A-5E or secured to another part for processing. For example, if the nozzle layer is not thick enough to be processed separately, then the nozzle layer can be bonded to another part (e.g., bonded to a fluid path body without the membrane and actuator or bonded to a descender layer) by, for example, anodic bonding, silicon-to-silicon direct wafer bonding, or using an adhesive (e.g., BCB). FIG. 8 is a SEM image showing a cross-sectional side view of a combination part 800 including a nozzle layer 801 (e.g., silicon) secured to a descender layer 802 (e.g., silicon). The nozzle layer 801 includes a plurality of nozzles 804 that are aligned with a plurality of descenders 806 formed in the descender layer 802. Similar to the process described above, an oxide layer can be applied to the combination part 800 and subsequently removed, and a second layer (e.g., a protective layer like oxide or metal) can be applied to the combination part 800, and finally it can be secured to a fluid flow path body (not shown).

In some implementations, the nozzle layer can be partially processed by itself, and completely processed after bonding the nozzle layer to another part. For example, the thermal oxide layer can be grown on and removed from the nozzle layer, and then the nozzle layer can be bonded to a fluid flow path body, after which, a protective layer can be applied to the nozzle layer. In other implementations, a nozzle layer is not oxidized rather a protective layer excluding thermal oxide can be applied to the surfaces of the nozzle layer that is already bonded to a fluid path body.

The use of terminology such as “inner” and “outer” and “top” and “bottom” in the specification and claims is to illustrate relative positioning between various components of the substrate, nozzle layer, and other elements described herein. The use of “inner” and “outer” and “top” and “bottom” does not imply a particular orientation of the substrate or nozzle layer. Although specific embodiments have been described herein, other features, objects, and advantages will be apparent from the description and the drawings. All such variations are included within the intended scope of the invention as defined by the following claims.

What is claimed is:

1. A nozzle layer comprising:
a semiconductor body having a first surface, a second surface opposing the first surface, and a nozzle formed through the body connecting the first and second surfaces, wherein the nozzle is configured to eject fluid through a nozzle outlet on the second surface; and
a metal layer around the outlet on the second surface and at least partially inside the nozzle, the metal layer inside the nozzle being completely exposed.

2. The nozzle layer of claim 1, wherein the metal layer comprises a metal selected from the group consisting of titanium, gold, platinum, rhodium, tantalum, nickel, and nickel chromium.

3. The nozzle layer of claim 1, wherein the metal layer is chemically resistant to alkaline fluids.

4. The nozzle layer of claim 1, further comprising a non-wetting coating on the metal layer on the second surface.

5. The nozzle layer of claim 1, wherein the metal layer is between about 0.1 micron and about 10 microns thick.

6. The nozzle layer of claim 5, wherein the metal layer has a thickness of about 1 micron or greater up to about 10 microns.

7. The nozzle layer of claim 1, wherein the metal layer is completely exposed around the outlet on the second surface.

8. The nozzle layer of claim 1, wherein the nozzle has tapered walls connecting the first surface to the second surface.

9. The nozzle layer of claim 1, wherein the nozzle has straight walls connecting the first surface to the second surface.

10. The nozzle layer of claim 1, wherein the metal layer shapes the outlet to have curved edges.

11. The nozzle layer of claim 10, wherein the curved edges have a radius of curvature of about 1 micron or greater.

12. The nozzle layer of claim 1, wherein the outlet is a square.

13. The nozzle layer of claim 1, wherein the semiconductor body comprises silicon.

14. A method comprising:
applying a metal layer around a nozzle outlet and at least partially inside a nozzle of a semiconductor nozzle layer; and
keeping the metal layer inside the nozzle completely exposed.

15. The method of claim 14, wherein applying the metal layer comprises sputtering metal.

16. The method of claim 15, wherein applying the metal layer further comprises electroplating metal on the sputtered metal.

17. The method of claim 14, further comprising securing the nozzle layer to a fluid flow path body.

18. The method of claim 14, further comprising keeping the metal layer around the nozzle outlet completely exposed.

19. The method of claim 14, wherein the nozzle outlet is located on an outer surface of the nozzle layer and the metal layer around the nozzle outlet is on the outer surface, and the method further comprises applying a non-wetting coating on the metal layer on the outer surface of the nozzle layer but not inside the nozzle.

20. The method of claim 14, wherein the metal layer has a thickness of about 1 micron or greater.

21. The method of claim 14, further comprising shaping the nozzle outlet using the metal layer to have curved edges.

22. The method of claim 21, wherein the curved edges have a radius of curvature of about 1 micron or greater.

23. A method of making nozzle layers:
measuring a plurality of nozzle outlet widths in a nozzle layer;
calculating an average nozzle outlet width of the plurality of nozzles;
calculating a thickness for a cover layer to be applied to the nozzle layer based on a comparison between the average nozzle width and a desired nozzle width; and
applying the cover layer with the thickness around each nozzle outlet and at least partially inside each nozzle.

24. The method of claim 23, wherein measuring a plurality of nozzle outlet widths includes using an optical measurement tool.

25. The method of claim 23, wherein the cover layer comprises metal.

26. The method of claim 25, wherein applying a metal layer comprises sputtering metal.

27. A kit, comprising:
a first print head including a first semiconductor body having a first surface and a first plurality of fluid flow paths through the first semiconductor body with a first plurality of apertures on the first surface, the first plurality of apertures having a first average lateral aperture dimension, and a first cover layer on the first surface and at least partially inside the first plurality of apertures to provide nozzles having a first average lateral nozzle dimension; and
a second print head including a second semiconductor body having a second surface and a second plurality of fluid flow paths through the second semiconductor body with a second plurality of apertures on the second surface, the second plurality of apertures having a second lateral aperture dimension different from the first average lateral aperture dimension, and a second cover layer on the second surface and at least partially inside the second plurality of apertures to provide nozzles having a second average lateral nozzle dimension approximately equal to the first average lateral nozzle dimension.
